(19) United States
(12) Patent Application Publication
(10) Pub. No.: US 2026/0343880 A1
(43) Pub. Date: Oct. 29, 2026

(54) METHOD FOR MANUFACTURING SEMICONDUCTOR DEVICE

(71) Applicant: HPSP Co., Ltd., Hwaseong-si, Gyeonggi-do (KR)

(72) Inventor: Sung-Kil CHO, Hwaseong-si, Gyeonggi-do (KR)

(21) Appl. No.: 19/114,514

(22) PCT Filed: Sep. 22, 2023
(86) PCT No.: PCT/KR2023/014466

§ 371 Date: Mar. 24, 2025

(30) Foreign Application Priority Data
Sep. 23, 2022 (KR) 10-2022-0120941

(51) Int. Cl. H10B 43/27

(52) U.S. Cl. CPC H10B 43/27

(57) ABSTRACT

The method for manufacturing a semiconductor device, according to an embodiment, may comprise the steps of: forming a thin-film structure on a substrate; forming a through-hole which passes through the thin-film structure; forming a channel layer which covers at least a part of the through-hole; performing a high-pressure surface treatment process for the channel layer; and performing an insulating layer formation process for the channel layer. In an embodiment, the step of performing the high-pressure surface treatment process may comprise a step of performing a high-pressure nitridation (HPN) process.

### CROSS-REFERENCE TO RELATED APPLICATION

This application is a National Stage application under 35 U.S.C. §371 of International Application No. PCT/KR2023/Ol4466, filed on Sep. 22, 2023, which claims the benefit of Korean Patent Applications No. 10-2022-0120941, filed on Sep. 23, 2022. The disclosures of the prior applications are incorporated by reference in their entireties.

### FIELD

The present disclosure relates to a method for manufacturing a semiconductor device.

### DESCRIPTION OF RELATED ART

A semiconductor device is a component mainly used in an electronic circuit or a similar device that uses the electrical conduction characteristics of a semiconductor. The semiconductor device may be classified into a memory semiconductor device and a non-memory semiconductor device. The memory semiconductor device may be classified into a volatile memory device such as DRAM and SRAM and a non-volatile memory device such as Mask ROM, EP ROM, EEP ROM, and flash memory.

FIGS. 1 and 2 illustrate a conventional process of manufacturing a semiconductor device.

Referring to FIG. 1, insulating layers 110 and gate layers 112 may be alternately and repeatedly deposited on a substrate 100 to form a thin-film structure TS.

Next, a through-hole H may be formed to extend through the thin-film structure TS so as to expose the substrate 100. In a plan view on an upper surface of the thin-film structure TS, the through-holes H may be two-dimensionally arranged.

Next, a semiconductor pattern SP may be formed to cover at least a portion of the through-hole H and expose the substrate 100. The semiconductor pattern SP may include a blocking layer 120 covering at least a portion of the through-hole H, a charge storage layer 130 formed on the blocking layer 120, and a first insulating layer 140 formed on the charge storage layer 130.

When the semiconductor pattern SP has been formed, a channel layer 150 covering the semiconductor pattern SP and the substrate 100 may be formed as illustrated in FIG. 1. The channel layer 150 may be a semiconductor material formed using one of atomic-layer deposition (ALD) or chemical-vapor deposition (CVD) techniques. The channel layer 150 may be, for example, a polycrystalline silicon film. According to an embodiment, the channel layer 150 may be an amorphous in the deposition thereof or may be crystallized using an annealing process, etc. In some embodiments, the channel layer 150 may be formed not to cover the substrate 100 so as to be exposed.

Thereafter, a trench pattern T may be formed in the channel layer 150 by patterning the channel layer 150.

Next, as shown in FIG. 2, a second insulating layer 160 may be formed in the trench pattern T of the channel layer 150 by performing an insulating layer forming process on the channel layer 150. However, when the second insulating layer 160 is formed without protecting the channel layer 150 in the process of forming the insulating layer 160, a portion of the channel layer 150, that is, a consumption area 170, is consumed in the process of forming the second insulating layer 160.

As described above, the consumption area 170 is generated during the manufacturing process of the semiconductor device. Thus, a thickness of the channel layer 150 does not meet a predetermined size, such that the electrical characteristics (e.g. V_{T} distribution) of the semiconductor device may be lowered.

In addition, the consumption area 170 is generated during the manufacturing process of the semiconductor device such that the conformality of the channel layer 150 is lowered, and thus, the electrical characteristics (e.g. V_{T} distribution) of the semiconductor device may be lowered.

### DISCLOSURE

### Technical Purpose

A purpose of the present disclosure is to provide a method for manufacturing a semiconductor device capable of improving an electrical characteristic of the semiconductor device by reducing a consumption area of a channel layer and at the same time, improving the conformality of the channel layer while an insulating layer is formed after forming the channel layer.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

### Technical Solution

A method for manufacturing a semiconductor device may include forming a thin-film structure on a substrate, forming a through-hole extending through the thin-film structure, forming a channel layer covering at least a portion of the through-hole, performing a high-pressure surface treatment process on the channel layer, and performing an insulating layer formation process on the channel layer.

In an embodiment, the performing of the high-pressure surface treatment process may include performing a high-pressure nitridation (HPN) process or a high-pressure fluorination (HPF) process.

In an embodiment, the high-pressure surface treatment process may be performed in a treatment apparatus into which a reactive gas including nitrogen or fluorine is injected under an inert gas atmosphere.

In an embodiment, a concentration of the reactive gas in the treatment apparatus may be 1% or higher, when the high-pressure surface treatment process is performed.

In an embodiment, the internal pressure of the treatment apparatus may be maintained at 2 to 100 atm, when the high-pressure surface treatment process is performed.

In an embodiment, the internal temperature of the treatment apparatus may be maintained at 200 to 1000 °C, when the high-pressure surface treatment process is performed.

In an embodiment, a trench pattern may be formed in the channel layer.

In an embodiment, a second insulating layer may be formed in the trench pattern by performing the insulating layer formation process on the channel layer.

The method may further include forming a semiconductor pattern between the through-hole and the channel layer.

In an embodiment, the semiconductor pattern may include a blocking layer covering at least a portion of the through-hole, a charge storage layer formed on the blocking layer, and a first insulation layer formed on the charge storage layer.

### Technical Effect

In the method for manufacturing the semiconductor device according to the embodiments, the channel layer consumption area is reduced and at the same time, the conformality of the channel layer is improved while the insulation layer is formed after the channel layer has been formed during the manufacturing process of the semiconductor device. Accordingly, electrical characteristics of the semiconductor device may be improved.

### BRIEF DESCRIPTION OF DRAWINGS

FIGS. 1 and 2 illustrate a conventional process of manufacturing a semiconductor device.

FIGS. 3 to 5 illustrate a process of manufacturing a semiconductor device according to an embodiment.

FIG. 6 is a graph illustrating a thickness of a channel layer of a semiconductor device manufactured by a conventional method for manufacturing a semiconductor device and a thickness of a channel layer of a semiconductor device manufactured by a method for manufacturing a semiconductor device according to an embodiment.

FIG. 7 is a graph illustrating conformality of a channel layer of a semiconductor device manufactured by a conventional method for manufacturing a semiconductor device and conformality of a channel layer of a semiconductor device manufactured by a method for manufacturing a semiconductor device according to an example embodiment.

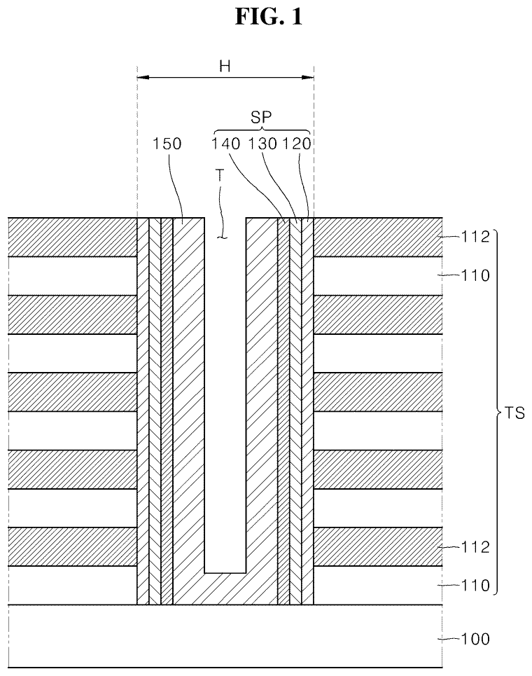

### DETAILED DESCRIPTIONS

The above-described purposes, features, and advantages will be described in detail with reference to the accompanying drawings, and accordingly, a person having ordinary skill in the art to which the present disclosure belongs will be able to easily implement the embodiments of the present disclosure. In describing the present disclosure, when it is determined that a detailed description of known technologies related to the present disclosure may unnecessarily obscure a gist of the present disclosure, the detailed description thereof will be omitted. Hereinafter, preferred embodiments of the present disclosure will be described in detail with reference to the accompanying drawings. In the drawings, the same reference numerals refer to the same or similar elements.

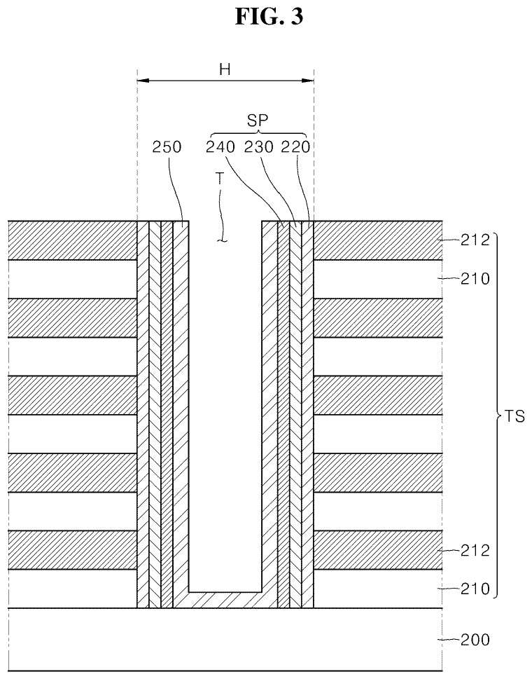

FIGS. 3 to 5 illustrate a process of manufacturing a semiconductor device according to an embodiment.

Referring to FIG. 3, insulating layers 210 and gate layers 212 may be alternately and repeatedly deposited on a substrate 200 to form a thin-film structure TS.

In an embodiment, the substrate 200 may be a silicon substrate, a germanium substrate, or a silicon-germanium substrate.

In an embodiment, the insulating layer 210 may be a silicon oxide film formed through a thermal-oxidation process, or a silicon oxide-film formed using a deposition technique. In one embodiment, the insulating layers 210 may have the same thickness. In another embodiment, some of the insulating layers 210 may have different thicknesses.

In an embodiment, the gate layer 212 may be made of a conductive material and may be a polycrystalline silicon film, or may include a material such as silicide or poly-side depending on an embodiment. In another embodiment, the gate layer 212 may include a metal material such as Al, Cu, W, etc.

In one embodiment, each of the insulating layer 210 and the gate layer 212 may be formed using thermal chemical-vapor-deposition (CVD), plasma enhanced chemical-vapor-enhanced CVD (PECVD), physical chemical-vapor-vapor deposition (PVD), or atomic layer deposition (ALD) process.

Next, a through-hole H may be formed to extend through the thin-film structure TS so as to expose the substrate 200. In a plan view on the upper surface of the thin-film structure TS, the through-holes H may be two-dimensionally arranged. The formation of the through-hole H may include forming a first mask pattern (not shown) having openings defined therein that define areas in which the through-holes H are to be formed on the thin-film structure TS, and anisotropically etching the thin-film structure TS using the first mask pattern as an etch mask. The first mask pattern may be made of a material having selectivity with respect to the insulating layer 210 and the gate layer 212. An upper surface of the substrate 200 may be over-etched by an etching process, so that a top portion of the substrate 200 may be recessed.

Next, a semiconductor pattern SP may be formed to cover at least a portion of the through-hole H and expose the substrate 100. The semiconductor pattern SP may include a blocking layer 220 covering at least a portion of the through-hole H, a charge storage layer 230 formed on the blocking layer 220, and a first insulating layer 240 formed on the charge storage layer 230. The semiconductor pattern SP may be deposited using, for example, a plasma enhanced chemical-vapor deposition (CVD) technique, a physical chemical-vapor deposition (CVD) technique, or an atomic layer deposition (ALD) technique.

When the semiconductor pattern SP is formed, a channel layer 250 covering the semiconductor pattern SP and the substrate 200 may be formed as illustrated in FIG. 3. The channel layer 250 may be a semiconductor material layer formed using one of atomic-layer deposition (ALD) or chemical-vapor deposition (CVD) techniques. The channel layer 250 may be, for example, a polycrystalline silicon film. According to an embodiment, the channel layer 250 may be amorphous in deposition or be crystallized using an annealing process, etc. In some embodiments, the channel layer 250 may be formed not to cover the substrate 200 so as to be exposed.

In the above-described embodiment, after the semiconductor pattern SP has been formed in the through-hole H, the channel layer 250 is formed on the semiconductor pattern SP. However, in another embodiment, only the channel layer 250 may be formed in the through-hole H without forming the semiconductor pattern SP.

When the channel layer 250 has been formed, a trench pattern T may be formed in the channel layer 250 by patterning the channel layer.

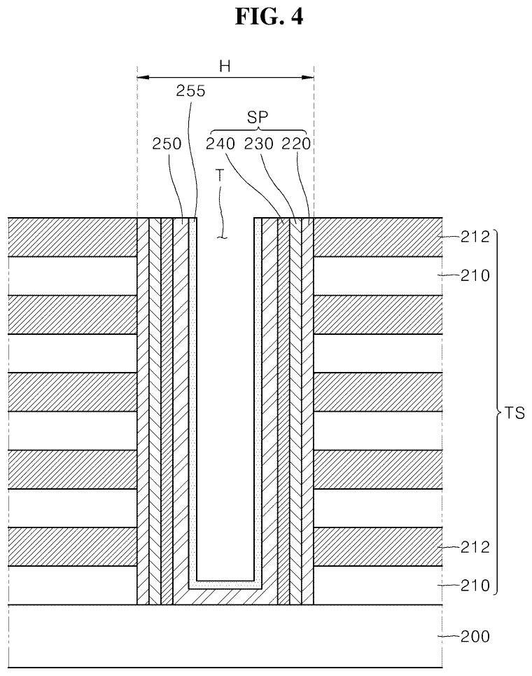

Next, as shown in FIG. 4, a high-pressure surface treatment process is performed on the channel layer 250 to form a protective layer 255 in the trench pattern T of the channel layer 250.

In an embodiment, the high-pressure surface treatment process performed on the channel layer 250 may include a High Pressure Nitridation (HPN) process or a High Pressure Fluorination (HPF) process.

In one embodiment, the HPN process may be performed within a treatment apparatus (e.g. a chamber or a furnace) into which a reactive gas containing nitrogen is injected under an inert gas atmosphere.

Examples of the inert gas include N₂, Ar, and He. However, the type of the inert gas is not limited thereto.

Examples of the reactive gas including nitrogen may include NH₂, NH₃, and the like. However, the type of the reactive gas including nitrogen is not limited thereto.

In one embodiment, a concentration of the reactive gas containing nitrogen in the processing apparatus when the HPN process is performed may be greater than or equal to 1%. For example, when the HPN process is performed, the concentration of the reactive gas including nitrogen in the treatment apparatus may be in a range of 1% to 100%.

In an embodiment, the internal pressure of the treatment apparatus may be maintained at 2 to 100 atm when the HPN process is performed.

In an embodiment, the internal temperature of the treatment apparatus may be maintained at 200 to 1000 °C when the HPN process is performed.

In an embodiment, the HPF process may be performed in a treatment apparatus into which a reactive gas including fluorine is injected under an inert gas atmosphere.

Examples of the inert gas include N₂, Ar, and He. However, the type of the inert gas is not limited thereto.

Examples of the reactive gas including fluorine include CF₄, C₂F₆, C₃F₈, NF₃, SF₆, WF₆, and HF. However, the type of the reactive gas including fluorine is not limited thereto.

In an embodiment, a concentration of the reactive gas containing fluorine in the treatment apparatus when the HPF process is performed may be greater than or equal to 1%. For example, when the HPF process is performed, the concentration of the reactive gas including fluorine in the treatment apparatus may be in a range of 1% to 100%.

In an embodiment, when the HPF process is performed, the internal pressure of the treatment apparatus may be maintained at 2 to 100 atm.

In an embodiment, the internal temperature of the treatment apparatus may be maintained at 200 to 1000 °C when the HPF process is performed.

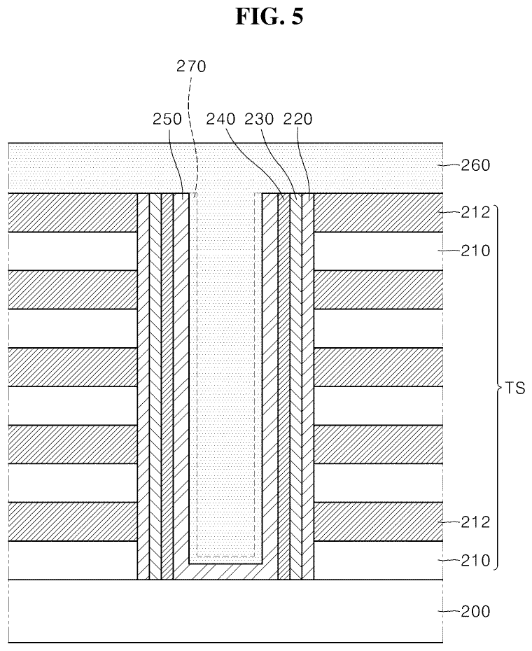

Next, as shown in FIG. 5, when the protective layer 255 has been formed in the trench pattern T of the channel layer 250 by performing the high-pressure surface treatment process on the channel layer 250, a second insulating layer 260 may be formed in the trench pattern T of the channel layer 250 by performing an insulating layer forming process on the channel layer 250. Examples of the insulating layer formation process include, but are not limited to, a deposition process of an insulating material (e.g. SiOₓ, SiN_{y}, etc.), or an oxidation process of the channel layer 250.

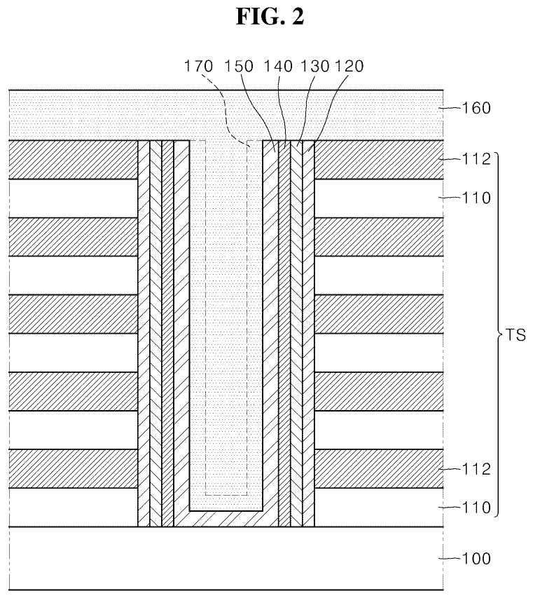

In the process of forming the second insulating layer 260, a portion of the channel layer 250, that is, a consumption area 270, may be consumed in the process of forming the second insulating layer 260. According to an embodiment, in the process of forming the second insulating layer 260, instead of forming the second insulating layer 260 directly on the channel layer 250, the second insulating layer 260 is formed on the protective layer 255. Therefore, a thickness or a volume of the consumption area 270 generated in the process of forming the second insulating layer 260 according to an embodiment may be smaller than a thickness or a volume of the consumption area 170 in the conventional semiconductor manufacturing process illustrated in FIG. 2.

In addition, since the second insulating layer 260 is formed on the protective layer 255 instead of forming the second insulating layer 260 directly on the channel layer 250 in the process of forming the second insulating layer 260, the conformality of the channel layer 250 may be improved compared to the conventional semiconductor manufacturing process illustrated in FIG. 2.

Since the second insulating layer 260 is formed after the protective layer 255 has been formed on the channel layer 250, the thickness of the channel layer 250 may be maintained at a predetermined value or greater, and the conformality of the channel layer 250 may be improved as compared with the conventional method. Accordingly, electrical characteristics of the semiconductor device may be improved.

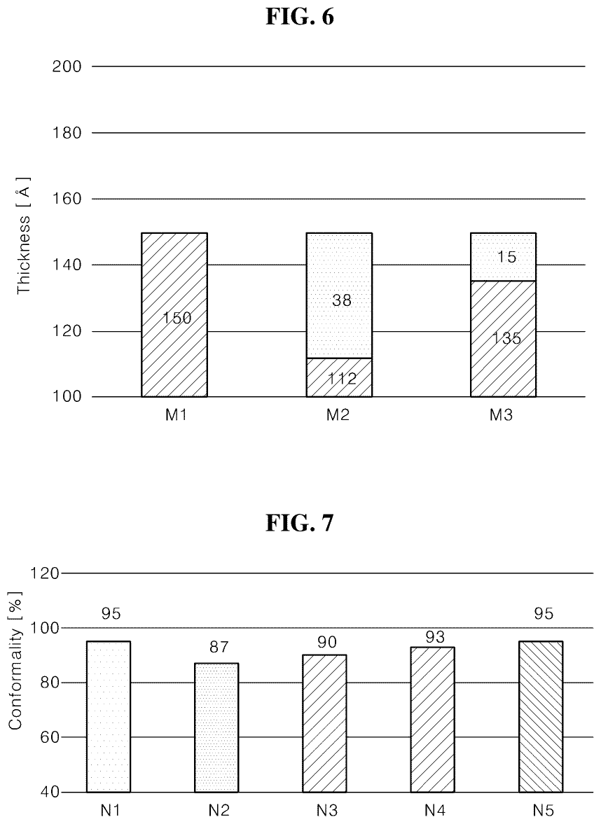

FIG. 6 is a graph illustrating a thickness of a channel layer of a semiconductor device manufactured by a conventional method for manufacturing a semiconductor device and a thickness of a channel layer of a semiconductor device manufactured by a method for manufacturing a semiconductor device according to an embodiment;

In FIG. 6, M1 denotes a thickness 150 of a channel layer measured before a process of forming an insulating layer on a channel layer is performed in a conventional method for manufacturing a semiconductor device or a method for manufacturing a semiconductor device according to an embodiment. Further, M2 denotes a thickness 112 of a channel layer and a thickness 38 of a consumption area after a formation process of an insulating layer directly on a channel layer is performed in a conventional method for manufacturing a semiconductor device. M3 denotes a thickness 135 of a channel layer and a thickness 15 of a consumption area after a high-pressure surface treatment process and an insulation layer formation process are sequentially performed on a channel layer in a method for manufacturing a semiconductor device according to an embodiment.

As shown in FIG. 6, when a process of forming an insulation layer directly on a channel layer is performed in a conventional method for manufacturing a semiconductor device, the channel layer is excessively consumed to increase the thickness 38 of the consumption area such that the thickness 112 of the channel layer is reduced.

However, according to a method for manufacturing a semiconductor device according to an embodiment, after the protection layer has been formed on the channel layer, the insulation layer formation process on the channel layer is performed. Accordingly, the channel layer is not directly consumed, such that the thickness 15 of the consumption area becomes smaller and the thickness 135 of the channel layer becomes larger than that in the semiconductor device manufactured according to the conventional method for manufacturing a semiconductor device. Therefore, the thickness of the channel layer may be maintained at a predetermined value, such that the electrical characteristics of the semiconductor device may be improved.

FIG. 7 is a graph illustrating conformality of a channel layer of a semiconductor device manufactured by a conventional method for manufacturing a semiconductor device and conformality of a channel layer of a semiconductor device manufactured by a method for manufacturing a semiconductor device according to an embodiment.

In FIG. 7, N1 denotes a conformality 95 of a channel layer measured before a process of forming an insulating layer on a channel layer is performed in a conventional method for manufacturing a semiconductor device or a method for manufacturing a semiconductor device according to an embodiment.

Further, the N2 denotes a conformality 87 of the channel layer measured after a formation process of an insulating layer directly on the channel layer is performed in a conventional semiconductor device manufacturing method.

In addition, N3 denotes a conformality 90 of the channel layer measured when the insulation layer formation process is performed after the high-pressure surface treatment process on the channel layer is performed while the internal pressure of the treatment apparatus is maintained at 5 atm in the method for manufacturing the semiconductor device according to an embodiment.

In addition, N4 denotes a conformality 93 of the channel layer measured when the insulation layer formation process is performed after the high-pressure surface treatment process on the channel layer is performed in a state in which the internal pressure of the processing apparatus is maintained at 10 atm in the method for manufacturing the semiconductor device according to an embodiment.

In addition, N5 denotes a conformality 95 of the channel layer measured when the insulation layer formation process is performed after the high-pressure surface treatment process on the channel layer is performed while the internal pressure of the processing apparatus is maintained at 20 atm in the method for manufacturing the semiconductor device according to an embodiment.

As shown in FIG. 7, the conformality 90, 93, and 95 of the channel layer measured when the insulating layer formation process was performed after the high-pressure surface treatment process is performed on the channel layer according to the method of fabricating the semiconductor device according to one embodiment is higher than the conformality 87 of the channel layer measured after the formation process of the insulating layer directly on the channel layer is performed in a conventional semiconductor device manufacturing method. That is, when the insulation layer formation process is performed after the high-pressure surface treatment process on the channel layer is performed, the conformality of the channel layer is improved compared to when the formation process of the insulating layer directly on the channel layer is performed in a conventional semiconductor device manufacturing method. Accordingly, electrical characteristics of the semiconductor device may be improved.

Further, as shown in FIG. 7, when the high-pressure surface treatment process on a channel layer is performed according to a method for manufacturing a semiconductor device according to an embodiment, the conformality of the channel layer may be improved as the internal pressure of the treatment apparatus increases.

Although the present disclosure has been described above with reference to the accompanying drawings, the present disclosure is not limited by the embodiments disclosed herein and the drawings, and it is obvious that various modifications may be made by those skilled in the art within the scope of the technical idea of the present disclosure. In addition, although the effects based on the configuration of the present disclosure are not explicitly described above in the description of the embodiment of the present disclosure, it is obvious that predictable effects from the configuration should also be recognized.

1. A method for manufacturing a semiconductor device, the method comprising:
forming a thin-film structure on a substrate;
forming a through-hole extending through the thin-film structure;
forming a channel layer covering at least a portion of the through-hole;
performing a high-pressure surface treatment process on the channel layer; and
performing an insulating layer formation process on the channel layer.

2. The method for manufacturing the semiconductor device of claim 1, wherein the performing of the high-pressure surface treatment process includes performing a high-pressure nitridation (HPN) process or a high-pressure fluorination (HPF) process.

3. The method for manufacturing the semiconductor device of claim 1, wherein the high-pressure surface treatment process is performed in a treatment apparatus into which a reactive gas including nitrogen or fluorine is injected under an inert gas atmosphere

4. The method for manufacturing the semiconductor device of claim 3, wherein a concentration of the reactive gas in the treatment apparatus is 1% or higher, when the high-pressure surface treatment process is performed.

5. The method for manufacturing the semiconductor device of claim 1, wherein an internal pressure of the treatment apparatus is maintained at 2 to 100 atm, when the high-pressure surface treatment process is performed.

6. The method for manufacturing the semiconductor device of claim 1, wherein an internal temperature of the treatment apparatus is maintained at 200 to 1000 °C, when the high-pressure surface treatment process is performed.

7. The method for manufacturing the semiconductor device of claim 1, wherein a trench pattern is formed in the channel layer,
wherein the insulating layer formation process is performed on the channel layer such that a second insulating layer is formed in the trench pattern.

8. The method for manufacturing the semiconductor device of claim 1, further comprising forming a semiconductor pattern between the through-hole and the channel layer.

9. The method for manufacturing the semiconductor device of claim 8, wherein the semiconductor pattern includes:
a blocking-layer covering at least a portion of the through-hole;
a charge storage layer formed on the blocking layer; and
a first insulating layer formed on the charge storage layer.
